(19) United States
(12) Patent Application Publication
(10) Pub. No.: US 2013/0193851 A1
(43) Pub. Date: Aug. 1, 2013

(54) Integrated Circuit Element and Electronic Circuit for Light Emitting Diode Applications

(71) Applicant: VISHAY DALE ELECTRONICS, INC., Columbus, NE (US)

(72) Inventors: Dan ALON, Providence, RI (US); Phil FABIS, Medfield, MA (US)

(73) Assignee: VISHAY DALE ELECTRONICS, INC., Columbus, NE (US)

(21) Appl. No.: 13/750,404

(22) Filed: Jan. 25, 2013

Related U.S. Application Data
(60) Provisional application No. 61/591,018, filed on Jan. 26, 2012.

(51) Int. Cl. H05B 37/02; H03H 7/00

(52) U.S. Cl. CPC H05B 37/02; H03H 7/00
USPC 315/121; 315/228; 323/369

(57) ABSTRACT

A system, method and circuit for providing constant current to an LED array are described herein. These include a resistor coupled to the LED array and a thermistor coupled to the LED array and the resistor. The resistor and the thermistor limit the current at a given temperature and compensate for the forward voltage shift of the LED array as a function of temperature. The system, method and integrated circuit may also include a fuse coupled to the thermistor. The fuse allows the system to continue to operate if a single LED within the LED array fails to short-circuit.

### PRIORITY CLAIM

This application claims the benefit of U.S. Provisional Application No. 61/591,018, filed Jan. 26, 2012, and is a continuation-in-part of U.S. patent application Ser. No. 13/012,960, filed Jan. 25, 2011, which claims the benefit of U.S. Provisional Application Nos. 61/298,123, filed on Jan. 25, 2010 and 61/345,746, filed on May 18, 2010, which are each incorporated herein by reference as if fully set forth.

### FIELD OF INVENTION

The present invention is directed to a circuit for providing constant current across a multitude of temperatures, and further provides a circuit element for light emitting diode (LED) applications.

### BACKGROUND

High-power white light emitting diodes (LEDs) are much more efficient lighting sources than conventional lighting sources. LEDs require constant DC current for optimal operation. However, driving high-power white LEDs with constant current is replete with issues. First, single high-power white LEDs are generally not capable of generating light flux comparable to conventional sources, such as incandescent or neon lights. For this reason, light sources based on white LEDs require large arrays of LED dies (instead of a single LED) to generate usable amounts of light. The use of larger arrays to increase the light flux increases the complexity of the driving circuit.

Additionally, the forward voltage of an LED die often suffers from high manufacturing tolerances. Typical forward voltage may be 3.5 volts, but may vary from approximately 3 to 4 V. These high tolerances further increase the complexity of the driving circuitry.

The LED forward voltage may also change rapidly as a function of junction temperature. For example, the temperature coefficient of voltage is typically in the range of −1000 ppm/° C. While the junction temperature may vary over 100° C., maintaining constant current as a function of temperature is another issue that increases the complexity of the driving circuitry.

In addition, LED failure modes include both short-circuit and open circuit. This uncertainty surrounding the failure mode of LEDs requires additional driver complexity to ensure that a single LED failure does not cause a total failure of the entire array.

Traditional stand-alone, low-power LEDs are driven by a constant voltage source and a current limiting resistor. An example of such a low-power LED driver circuit is shown in “The Art of Electronics,” P. Horowitz et al, 1989, p. 325. While this driver circuit is simple, robust and cheap, the circuit does not compensate for the temperature coefficient or a short-circuit failure mode in powering high-power white LEDs. Other solutions include elaborate driver circuitry which provides excellent performance, but suffers from significant costs.

Thus, there exists a need for a system and method that drives LED arrays by providing constant current to the large arrays of LEDs, while accounting for the tolerances associated with the forward voltage, the variations of current versus temperature and the LED failure modes, and other technical difficulties, all the while maintaining simplicity and low-cost.

### SUMMARY OF THE EMBODIMENTS

A system for providing constant current to an LED array is disclosed. The system includes a resistor coupled to the LED array and a thermistor coupled to the LED array and the resistor. The resistor and thermistor operate in conjunction to limit the current at a given temperature and to compensate for the forward voltage shift of the LED array as a function of temperature. The system may optionally include a fuse, coupled to the thermistor, allowing the system to operate if a single LED within the LED array fails to short-circuit.

A circuit for providing constant current to an LED array is disclosed. The circuit includes a substrate, a high TCR (Temperature Coefficient of Resistance) resistive film (Thermistor), a low TCR resistive film and at least one LED. The resistor and thermistor operate in conjunction to limit the current at a given temperature and to compensate for the forward voltage shift of the LED array as a function of temperature. The integrated circuit may optionally include a thin film fuse coupled to the thermistor allowing the system to operate if a single LED within the LED array fails to short-circuit. It is noted that the high TCR and low TCR resistors may be replaced by a single resistor of the equivalent value and TCR. By way of example, this assembly may include a layer of Nickel (Ni) over Tantalum Nitride (TaN) formed on a ceramic substrate forming a Ni thermistor serially coupled to Tantalum Nitride resistor serially coupled to the LED array and the thermistor.

A method of providing an LED with constant current is disclosed. The method includes identifying portions of the LED array to power in parallel, identifying a resistor to limit current at a certain temperature, matching a thermistor to compensate for the forward voltage shift of the LEDs, and powering the LED with a constant voltage source.

### BRIEF DESCRIPTION OF THE DRAWINGS

Understanding of the present invention will be facilitated by consideration of the following detailed description of the preferred embodiments of the present invention taken in conjunction with the accompanying drawings, in which like numerals refer to like elements:

FIG. 1 is a diagram of an electrical array for providing high-power light from LEDs driven at a constant current;

FIG. 2 is a graph of the forward voltage shift corresponding to the junction temperature of a typical high-power white LED;

FIG. 3A is a circuit operable in the system of FIG. 1;

FIG. 3B is a circuit operable in the system of FIG. 1;

FIG. 4A is a circuit operable in the system of FIG. 1;

FIG. 4B is a circuit operable in the system of FIG. 1;

FIG. 4C is a circuit operable in the system of FIG. 1;

FIG. 5 is a metallic structure that allows the integration of a circuit operable in the system of FIG. 1 in a single surface mount component;

FIG. 6 illustrates the trimming of the metallic structure of FIG. 5;

FIG. 7 illustrates a top view of a termination chip manufactured on a ceramic substrate embedding a circuit operable in the system of FIG. 1;

FIG. 8A illustrates an LED package to include termination chip of FIG. 7, an LED die, an ESD protection die, wire-bonds, and encapsulating compound;

FIG. 8B illustrates an LED package to include an LED die, a circuit operable in the system of FIG. 1, an ESD protection die, wire-bonds, and encapsulating compound;

FIG. 9 is a flow diagram of a method of providing an LED with constant current; and

FIGS. 10A, 10B and 10C illustrate the system of FIG. 1 adapted to provide high-power light from LEDs driven at a constant current by an AC source.

### DETAILED DESCRIPTION OF THE EMBODIMENTS

It is to be understood that the figures and descriptions of the present invention have been simplified to illustrate elements that are relevant for a clear understanding of the present invention, while eliminating, for the purpose of clarity, many other elements found in electrical circuits and circuit design. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

A system, method and circuit for providing constant current to an LED array are described herein. These include a resistor electrically coupled to the LED array and a thermistor electrically coupled to the LED array and the resistor. The resistor and thermistor operate in conjunction to limit the current at a given temperature and to compensate for the forward voltage shift of the LED array as a function of temperature. The system, method and circuit may optionally include a fuse coupled to the thermistor. The fuse allows the system to operate if a single LED within the LED array fails to short-circuit.

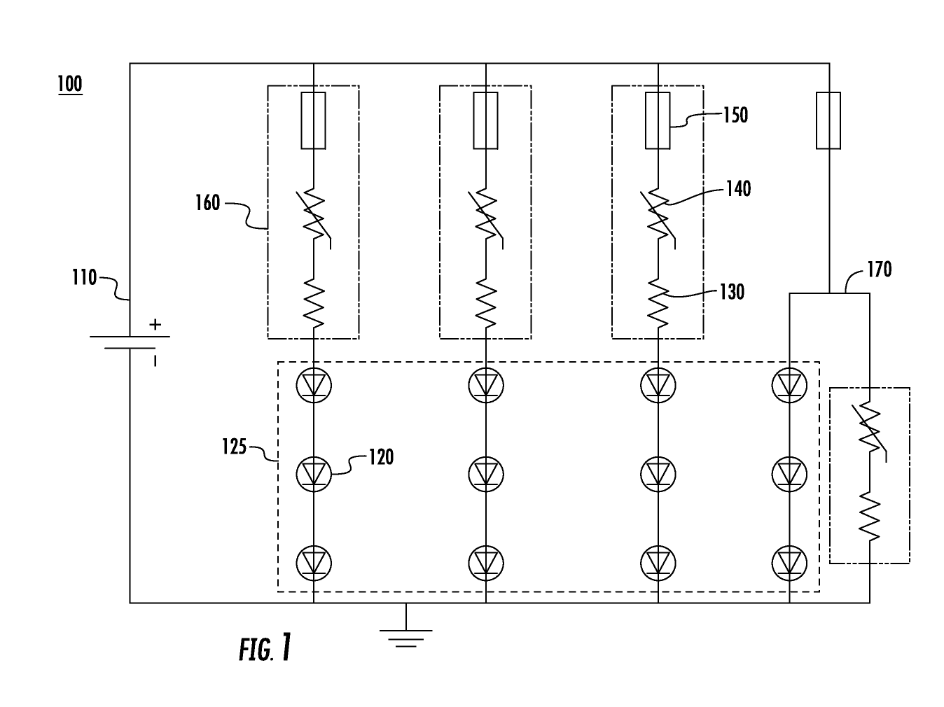

FIG. 1 illustrates a system 100 for providing high-power light from LEDs driven at a constant current. System 100 includes a constant voltage source 110, an array 125 of LEDs 120, a plurality of resistors 130, a plurality of thermistors 140, and optionally a plurality of fuses 150. Resistor 130, thermistor 140, and fuse 150 may be formed into a circuit element 160 for one or more associated LEDs 120. Although three LEDs 120 are shown in series with an associated resistor 130, thermistor 140, and fuse 150, those of skill in the art would realize that more or less LEDs 120 may be utilized. Although the LEDs 120 are shown in series with the circuit 160, those of skill in the art would realize that a parallel topology may be utilized. A parallel configuration is shown in FIG. 1 as circuit 170. Specifically, there is a fuse 150 coupled to the positive side of source 110. Coupled to fuse 150 distal to the positive side of source 110, there is a parallel configuration of LEDs 120 in parallel with resistor 130 and thermistor 140. Additionally, although array 125 comprises multiple sets of LEDs 120, those of skill in the art would realize that this depiction is only an example and more or less sets of LEDs 120 may be utilized.

As shown in the series configurations, resistor 130, thermistor 140 and optional fuse 150 are coupled together in series forming a circuit element 160. While system 100 is shown with the majority of the circuit elements in series, the present invention is not so limited. Other configurations may be configured from the description herein. As shown, circuit element 160 is coupled in series with three LEDs 120 of array 125 as an example. Circuit 170 is coupled in parallel with three LEDs 120 of array 125 in parallel with resistor 130 and thermistor 140.

Voltage source 110 is a circuit element that, in an ideal scenario, has a voltage across it independent of the current through it. Voltage source 110 supplies a constant DC or AC potential between its terminals for any current flow through it. Voltage source 110 may take the form of any source of electrical energy, such as one or more batteries, generators, or power systems.

LEDs 120 may be accumulated in array 125 (shown as twelve LEDs arranged with three LEDs in series of four parallel strings, although any number may be used) in order to provide high-power white light output with the light flux comparable to alternative sources such as incandescent lights or neon lights. Array 125 may generate usable amounts of light. Array 125 is optimally operated with a constant DC current. “LED array” or “array” is used to describe a network of one or more series strings of one or more LEDs.

A constant current is provided by circuit 160. This constant current is achieved using thermistor 140 and resistor 130. Resistor 130 and thermistor 140 each have associated resistance values R130 and R140 and associated temperature coefficient of resistance (TCR) values TCR130 and TCR140. The terms ‘resistor’ and thermistor' as used herein illustrate that TCR140>TCR130. By tuning the values associated with resistor 130 and thermistor 140, the total resistance R160 and TCR160 may be controlled. For example, in the series configuration presented in FIG. 1, the total equivalent value for resistance R160 is R130+R140. The total equivalent value for TCR TCR160 is (R130*TCR130+R140*TCR140)/(R130+R140). In effect, circuit 160 is a trimable thermistor. Circuit 160 may be used to simultaneously limit the current through LED array 125 and compensate for the temperature drift of the LED forward voltage.

Resistor 130 may take the form of a circuit element that is a two-terminal passive electronic component implementing electrical resistance. Resistor 130 may be made of various materials, compounds, wires or films. The resistor technologies of elements 130 and 140 are not necessarily the same. The LEDs are characterized by temperature coefficient of forward voltage as described in FIG. 2. At a given constant current value, the LEDs exhibit a temperature dependent voltage drop that behaves similarly to the voltage drop across a resistor as described by Ohm's law. This temperature dependent voltage drop at a given constant current is equivalent to TCR. By way of example, the technology used for element 130 may be characterized by TCR values smaller than those of the LEDs and the technology used for element 140 may be characterized by TCR values larger than those that characterize the LEDs. By combining elements 130 and 140 in the electric circuit, an effective value of TCR may be obtained that negates that of the LEDs.

Resistor 130 may be made from a mixture of finely ground or powdered conductive materials and insulating materials, with or without organic additives, using a technology commonly referred to as thick film. By carefully controlling the composition of the film, a single resistor may be created with the desired value and TCR to perform the task of circuit 160 as described herein. In such a configuration, thermistor 140 may be removed from the circuit. Alternatively, resistor 130 may take the form of a foil resistor, which is a special alloy foil, several micrometers thick. Foil resistors exhibit high precision and stability. Additionally, foil resistors have a low TCR even as low as a TCR of 0.14 ppm/° C.

Electrically coupled to resistor 130 is thermistor 140. Thermistor 140 is a type of resistor where the resistance varies predictably with temperature. Thermistor 140 may operate as an inrush current limiter and overcurrent protector. Thermistor 140 may be made of various materials, compounds, wires or films, such as a metal film including nickel, platinum, palladium or silver, for example. Thermistor 140 may be alternatively a ceramic or polymer and may be made from a pressed disc or cast chip of a semiconductor, such as a metal oxide. Thermistor 140 may also take other forms as described hereinbelow.

Referring now additionally to FIG. 2, there is illustrated the forward voltage shift corresponding to the junction temperature of a typical high-power white LED. A typical forward voltage of an LED at 25° C. is approximately 3.5 volts. As may be seen in FIG. 2, for a junction temperature of 25° C., the voltage shift may be zero. As the junction temperature increases to 100° C., this voltage shift may be as large as −0.3 V. The forward voltage shift at 150° C. may be as large as −0.5 V. As may be seen in the illustration of FIG. 2, the LED forward voltage changes rapidly with junction temperature, although this change is substantially linear. The temperature coefficient of voltage is approximately −1000 ppm/° C.

Element 160 may include resistor 130, thermistor 140 and fuse 150. The total TCR of element 160 may compensate for the forward voltage shift of LED 120 as a function of temperature. Element 160 may be designed to compensate for the junction temperature illustrated and described with respect to FIG. 2. That is, the combination of elements 130 and 140 may be designed to counteract the forward voltage shift corresponding to the junction temperature of the LED by applying approximately a 1000 ppm/° C. Circuit element 160 may have a resistance in the range of 0.1Ω to 10Ω for example, and may exhibit a TCR value of approximately 1000 ppm/° C. or higher. The values of 10Ω and 1000 ppm/° C. are application specific and may depend on the number of LEDs in the array. As such, for large arrays, these values may be required to be >>10Ω and >>1000 ppm/° C.

The desired values for resistors 130 and 140 can be selected using the following considerations. It is noted that the following equations represent a first approximation of the correct values. Additional considerations, such as self heating of the thermistor and thermal coupling between the LED and the thermistor, are not described, but are well known to those of ordinary skill in the art. The resistance of circuit element 160, denoted as R160, and the temperature coefficient of resistance of circuit element 160, denoted as TCR160, may be defined using the following equations:

R160=(Vcc−Vf)/I Equation (1)

TCR160=−1*TCVf*Vf/R160/I Equation (2)

where Vcc is the constant common-collector voltage, I is the desired constant current, TCVf is the temperature coefficient of the forward voltage and Vf is the nominal forward voltage. It is noted that those skilled in the art would recognize that a similar derivation can be made for an AC supply. In this case, resistors and/or capacitors may be used to limit current and compensate for temperature drifts.

The values of R160 and TCR160 may be trimmed to a desired value to compensate for a string of LEDs. Alternatively, these values may be set to compensate for a single LED. The later configuration has the added advantage of providing a method to compensate for the variation in forward voltages related to the large manufacturing tolerances associated with an LED. In compensating for a single LED, the value of circuit 160 may be trimmed to accommodate the actual Vf of the associated LED.

Fuse 150 may be included to allow array 125 to continue to operate in the event that a single LED fails as a short-circuit, for example. Although fuse 150 is described as included within system 100, fuse 150 is not needed, and may only optionally be included within system 100. That is, fuse 150 may be removed from system 100. Fuse 150 may be a sacrificial overcurrent protection device that includes a metal wire or strip that melts when too much current flows. The melted strip interrupts the circuit in which it is connected. Short circuit, overload or device failure, such as a failure of LED 120, is often the reason for excessive current. A fuse interrupts excessive current so that further damage to the remainder of system 100 by overheating or fire is prevented and continued operation is permitted. Fuse 150 may be specifically selected to allow for passage of normal current, and excessive current for short periods.

Fuse 150 may include a metal strip or wire fuse element, (typically having a small cross-section compared to the circuit conductors), mounted between a pair of electrical terminals. This strip may be enclosed by a non-conducting and non-combustible housing. Fuse 150 may be arranged in series with resistor 130, thermistor 140 and LEDs 120, to carry all the current passing through the protected circuit. The resistance of fuse 150 generates heat due to the current flow. The size and construction of fuse 150 may be determined so that the heat produced for a normal current does not cause fuse 150 to attain too a high temperature for the overall design of the system 100. If too high a current flows, fuse 150 rises to a higher temperature and either directly melts, or else melts a soldered joint within the fuse, opening system 100. When the metal conductor parts, an electric arc forms between the un-melted ends of the element. The arc grows in length until the voltage required to sustain the arc is higher than the available voltage in the circuit, thereby terminating current flow.

Fuse 150 may be made of metal such as zinc, copper, silver, aluminum, or alloys thereof. Fuse 150 may be designed to carry its rated current indefinitely, and melt quickly on a small excess from the normal current. Fuse 150 may be unaffected by minor harmless surges of current within a desired range, and may be protected against oxidization or other changes. Fuse 150 may include elements shaped to increase a heating effect. The fuse element may be surrounded by air, or by materials intended to speed the quenching of the arc. Silica sand or non-conducting liquids may be used. Fuse 150 may “blow” and provide an open circuit, such as along one of the serial pathways of FIG. 1. Once blown, the serial pathway may have zero current flow, enabling the other serial paths to operate without disruption. Fuse 150 may be rated in the range of 10 mA to 1 A for example, with a 24 Volt rating. Further, fuse 150 may have a time-current characteristic of 5 seconds.

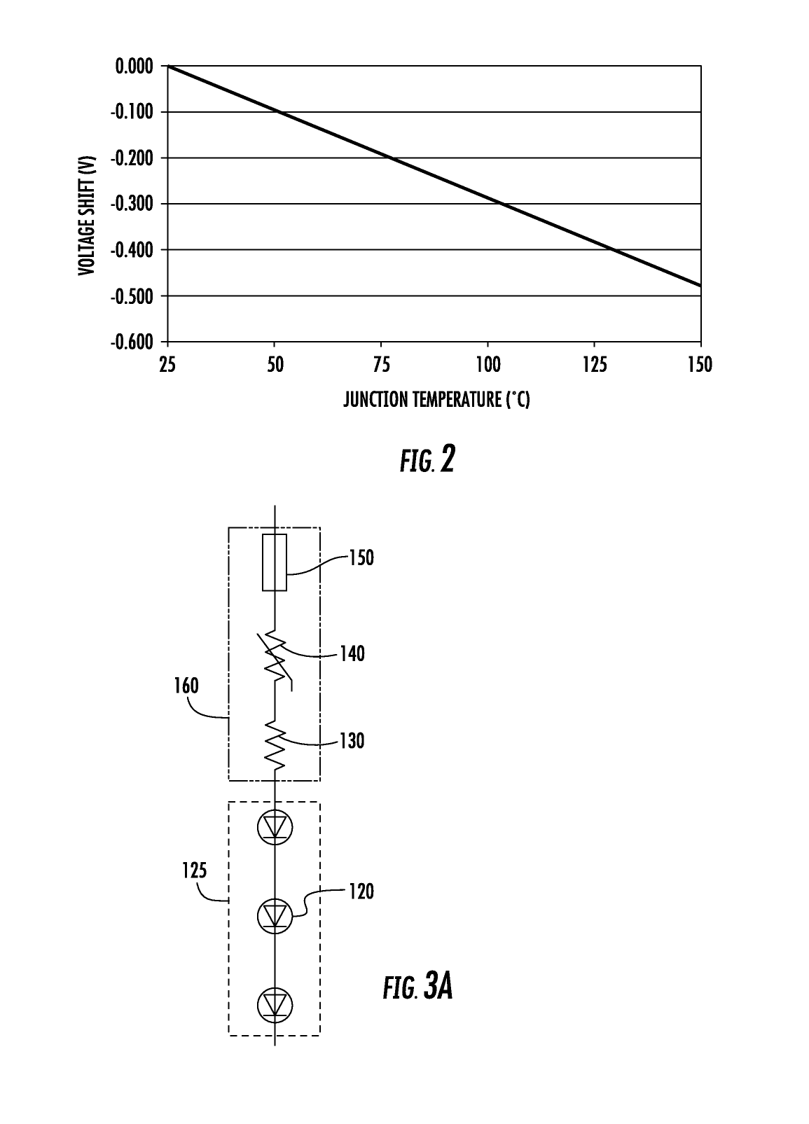

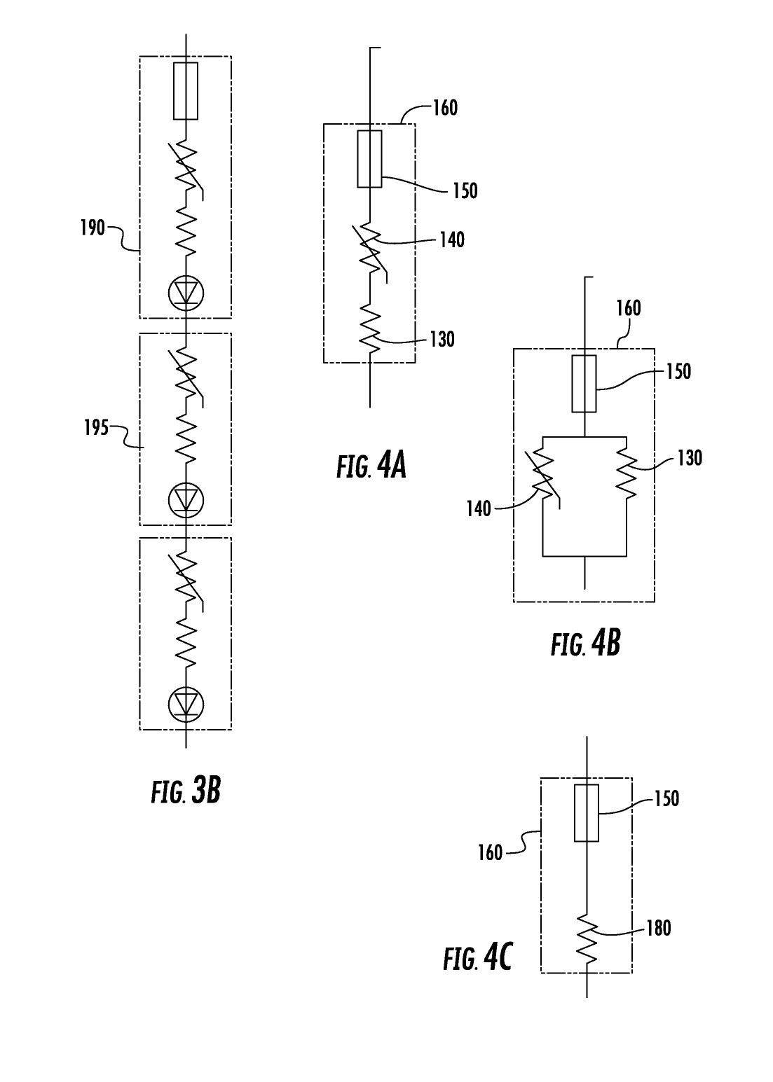

Referring now to FIG. 3A, there is shown a circuit configuration operable in the system of FIG. 1. Specifically, FIG. 3A depicts circuit 160 including resistor 130, thermistor 140, and fuse 150, coupled in series with a string of three LEDs 120 making up array 125. Much of the discussion with respect to the serial configuration of FIG. 1 has focused on this configuration of circuit 160.

Referring now to FIG. 3B, there is shown another configuration operable in the system of FIG. 1. Specifically, FIG. 3B depicts a circuit configuration with resistor 130, thermistor 140, and fuse 150 matched with an LED 120. Such a configuration is depicted by circuit element 190. Also illustrated in FIG. 3B, circuit element 195 depicts a coupling of resistor 130, thermistor 140 and an LED 120. Circuit element 195 is similar to circuit element 190, except for omitting fuse 150. Fuse 150, when optionally employed, is only needed once for a single serial configuration shown in FIG. 3B. That is, there is no need for multiple fuses 150 in the series configuration shown. One advantage that may result from the configuration depicted in FIG. 3B is that the thermistor 140 may achieve improved thermal coupling with the associated LED 120 when the thermistor 140 and LED 120 are uniquely matched and are in close proximity.

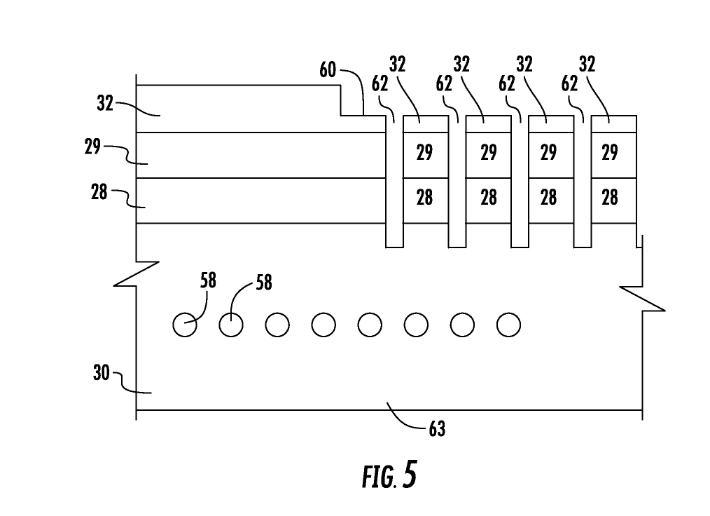

Generally, FIGS. 4A-C illustrate three configurations of circuits 160 of the myriad of circuits that may be used in system 100.

As discussed with respect to FIG. 1, circuit 160 may be configured with resistor 130, thermistor 140, and optionally may include fuse 150. Element 160 may be designed in a series and/or parallel configuration, as illustrated in FIGS. 4A and 4B respectively.

Alternatively, the combination of resistor 130 and thermistor 140 may be replaced by a single resistive element 180 with equivalent value and TCR. Such a single resistive element 180 is illustrated in FIG. 4C. Single resistive element 180 may be fabricated by formulating a paste with the desired resistance and thermal coefficient of resistance. The term ‘thick-film’ is commonly used to describe the technology of manufacturing resistors with the use of pastes. Generally, the thick film configuration can only be trimmed to value. The thermal coefficient of resistance cannot be manipulated by trimming and must be controlled by adjusting the formulation of the paste from which the element 180 is manufactured.

Circuit 160 may be formed on a ceramic substrate with a combination of Ni and TaN resistive thin films. One method of construction is described in U.S. Pat. No. 4,464,646, which is herein incorporated by reference as if set forth in its entirety and which demonstrates the creation of a circuit element with trimable value and TCR using thin-film production techniques. The values of resistor 130 and thermistor 140 may be trimmed to achieve the desired value and temperature coefficient.

Alternatively, resistors 130 and 140 may be fabricated using metal strip technology. Metal strip technology, such as is described in U.S. Pat. No. 5,604,477, for example, may be constructed of three metal strips joined together in an edge to edge relation. The disclosure of U.S. Pat. No. 5,604,477 is hereby incorporated by reference as if set forth in the entirety herein. The outer two metal strips are made of a highly conductive material of which the surface mount terminations are constructed. The center metal strip is made of a material of which the resistive element is fabricated. This center metal strip can be laser trimmed to the desired value. Circuit element 160 disclosed herein may be fabricated by adding a fourth metal strip, as illustrated in FIG. 5.

Referring now to FIG. 5, there is illustrated an enlarged view of a metal strip structure allowing the integration of a circuit operable in the system of FIG. 1 in a single surface mount component. As illustrated in FIG. 5, strip 28 may be made of a material with high resistivity and low TCR. Strip 29 may be made of a material with high resistivity and high TCR. Lower strip 30 and upper strip 32 may each be made of a material with high conductivity. The term ‘high resistivity’ is used to illustrate that both strips 28 and 29 contribute much of the total resistivity of the component. The term ‘high conductivity’ associated with strips 30 and 32 illustrate that these strips do not contribute significantly to the total resistance of the component. The four strips may be connected in an edge to edge relation as the connection for the three strip configuration in U.S. Pat. No. 5,604,477. For example, strips 28, 29, 30, and 32 may be welded together and trimmed to length. A plurality of index holes 58 may be provided to enable alignment in future operations. Separating slots 62 may be formed by punching or other conventional means. Slots 62 form individual resistor blanks of the proper width from the continuous strip of material, and to electrically isolate each resistor bank so that resistance readings may be taken and the elements trimmed as needed. Slots 62 extend downwardly through upper strip 32, strip 29, strip 28, and partially through lower strip 30, while leaving a connected portion 63 at the lower edge of strip 30 to provide for continuous processing of the strips. Upper strip 32 may become an upper edge 60 of each resistor blank. Other mechanisms established to facilitate the manufacturability of the surface mount component described in U.S. Pat. No. 5,604,477 may be used for the disclosed four strip configuration.

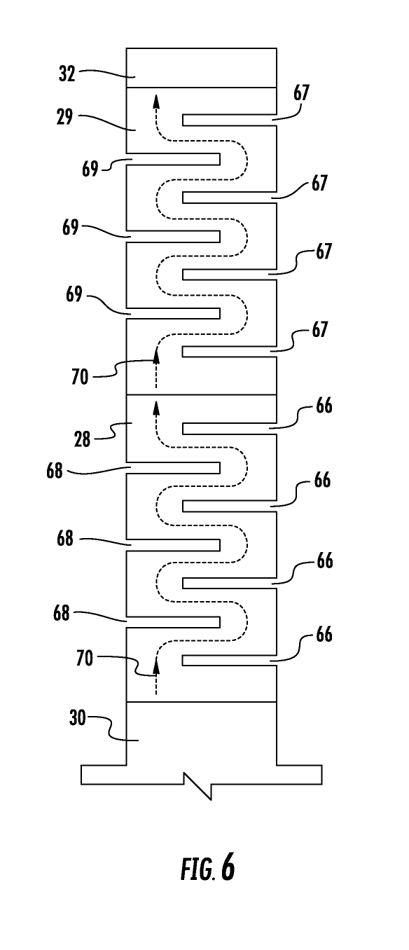

Adjustment and calibration of the resistor blank of FIG. 5 may be achieved with reference to FIG. 6. Each resistor blank may be adjusted to the desired resistance and TCR. The four metal strip configuration, as illustrated in FIG. 6, may be simultaneously trimmed to resistance and TCR by cutting a first set of slots 66 and 68 through strip 28 and a second set of slots 67 and 69 in strip 29. Slots 66 and 68 trim the low TCR strip 28 to a first value and slots 67 and 69 trim the high TCR strip 29 to a second value, the combination of which return the desired resistance and TCR of the integrated circuit. In each case by making slots 66 and 68 and/or slots 67 and 69, a serpentine current path is formed designated by path 70. This serpentine path 70 increases the resistance of the integrated circuit. The slots 66, 67, 68, 69 may be formed using a laser beam or any other instrument used for cutting metallic materials. The resistance and TCR of each circuit may be continuously monitored during the trimming. Although the described embodiment depicts a series configuration, it is understood that parallel configurations may also be used.

During operation, to achieve sufficient TCR tracking between the LED and circuit 160, the LED may be thermally coupled to circuit 160. Thermal coupling of circuit 160 may be achieved by locating circuit 160 proximate to the LED. Circuit 160 and its associated LED may also be housed in the same package thereby aiding in the thermal coupling. For example, circuit 160 may be integrated in a metal package for electronic components as described in U.S. patent application Ser. No. 13/012,960. The metal package for electronic components may include a metal base and a termination chip coupled to the metal base. FIG. 7 illustrates a top plan view of a termination chip manufactured on a ceramic substrate. The termination chip 325, as illustrated in FIG. 7, may include a die contact pad 305 electrically coupled by via 310 to a soldering pad 315 on the back side of the chip. Top, bottom and side pads 300 may be designed to allow the termination chip 325 to be soldered directly to the metal base. As specifically shown, circuit 160 including resistor 130 and thermistor 140 may be embedded in the termination chip 325. In such an embedded configuration, resistors 130 and 140 may be placed in series between die contact pad 305 and via 310. Alternatively, circuit 160 may be assembled on termination chip 325. Each termination chip configuration may aid in matching the values of circuit 160 to the given properties of the LED. By trimming the values of element 130 and 140 to match those of the LED, as described hereinabove, the variations in forward voltage originating in production tolerances of the LED may be corrected. The resulting assembly may include a tight tolerance in overall voltage drop across the packaged LED, an integrated LED and current limiting resistor, an eternal compensation for temperature drifts resulting in a relatively stable packaged component, and optionally an integrated fuse element (not shown in FIG. 7) to reduce the risk that a single LED failure can short the entire LED array.

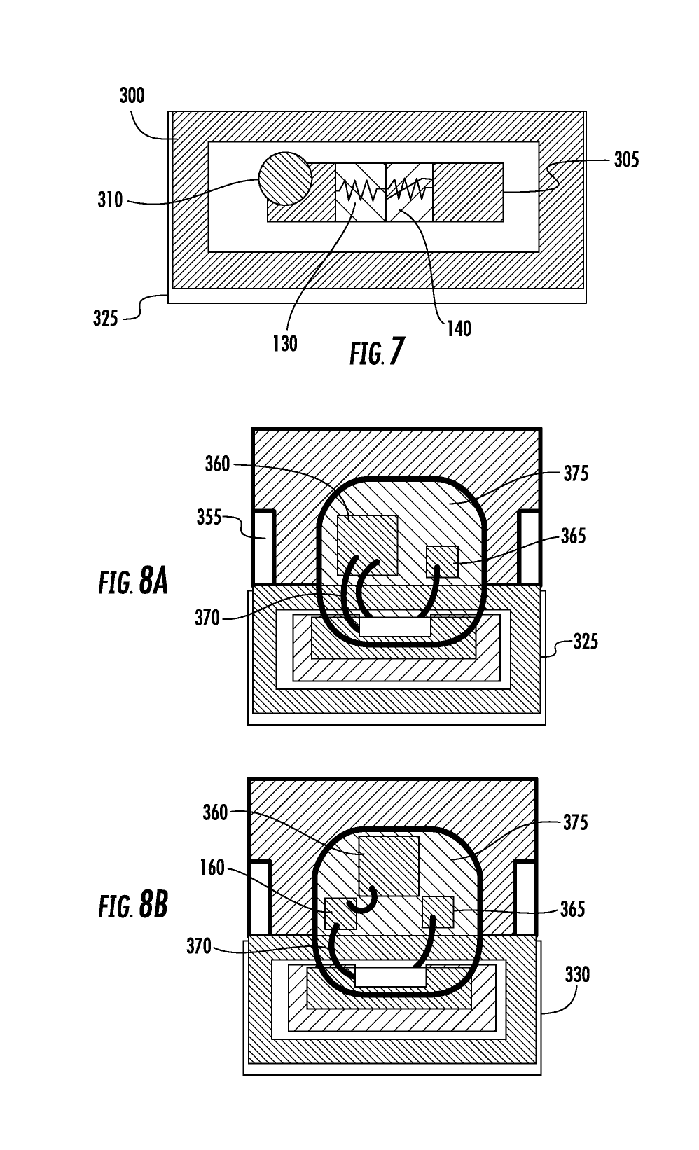

FIG. 8A illustrates a packaged LED utilizing the termination chip of FIG. 7. The assembly includes a metal base 375 and a termination chip 325. Termination chip 325 includes circuit 160. Alternatively, circuit 160 may be included as a discrete component (or components) housed inside the package and connected by wire bonds as shown in FIG. 8B. In the example illustrated in FIGS. 8A-B, a high power LED die 360, an ESD protection diode 365, and circuit element 160 may be packaged and interconnected using bond wires 370. LED die 360, diode 365, and/or circuit element 160 may be attached to the metal base via a eutectic bond, for example. A clear molding compound 375 may be added to the molding cavity to complete the assembly.

Various other packaging technologies may also be used to house circuit 160 in close proximity to the LED die. For example, packages based on highly thermally conductive ceramic substrates, packages based on low temperature co-fired ceramic (LTCC) or molded compounds with metal lead frames, optionally including a metal heat sink, and/or packages based on metal-core or metal-backed printed circuit boards may be used.

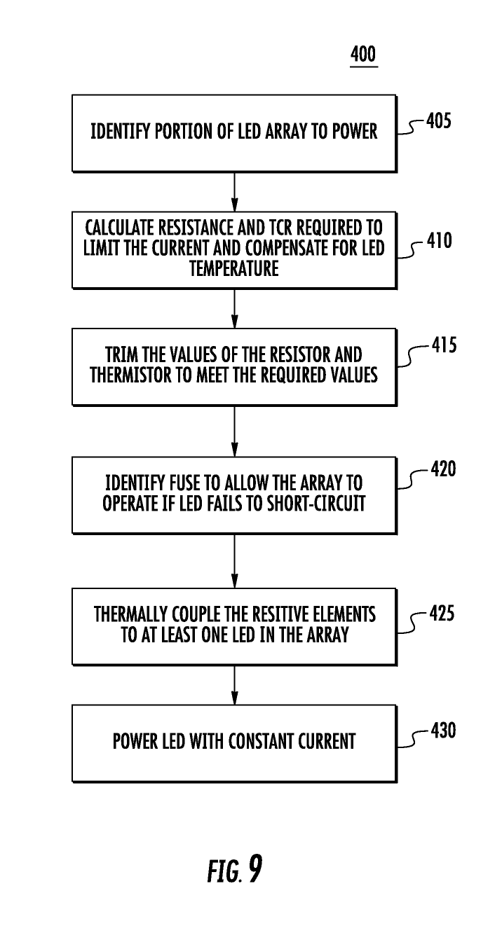

FIG. 9 illustrates a method 400 of providing an LED with constant current. Method 400 includes identifying portions of the LED array to power at step 405. Method 400 includes step 410 identifying a resistance value and a TCR value adequate to limit the current through the portions of the LED array identified at 405. The desired resistance and TCR may be achieved by tuning the values of resistor 130 and thermistor 140. The desired resistance and TCR may be implemented at step 415 resulting in a tuned circuit that may limit the current, compensate for manufacturing tolerances and reduce the temperature drift of the identified portion of the LED array. Optionally, method 400 may include identifying a fuse to allow the array to operate if an LED fails to short-circuit at step 420. Method 400 includes step 425 thermally coupling circuit 160 to the LEDs identified at step 405. Method 400 includes powering the identified portion of the LED array with constant current through the circuit of the present invention at step 430.

The present circuit, system and integrated circuit provide the ability to drive an LED array capable of providing comparable flux with constant current while accounting for the forward voltage issues and LED failure modes. As described hereinabove, the circuit for optimal operation of LEDs requires constant DC current. The circuit of the present invention may also operate an LED in a home or office based lighting application because of the ability to function with traditional dimmer fixtures in an AC LED configuration.

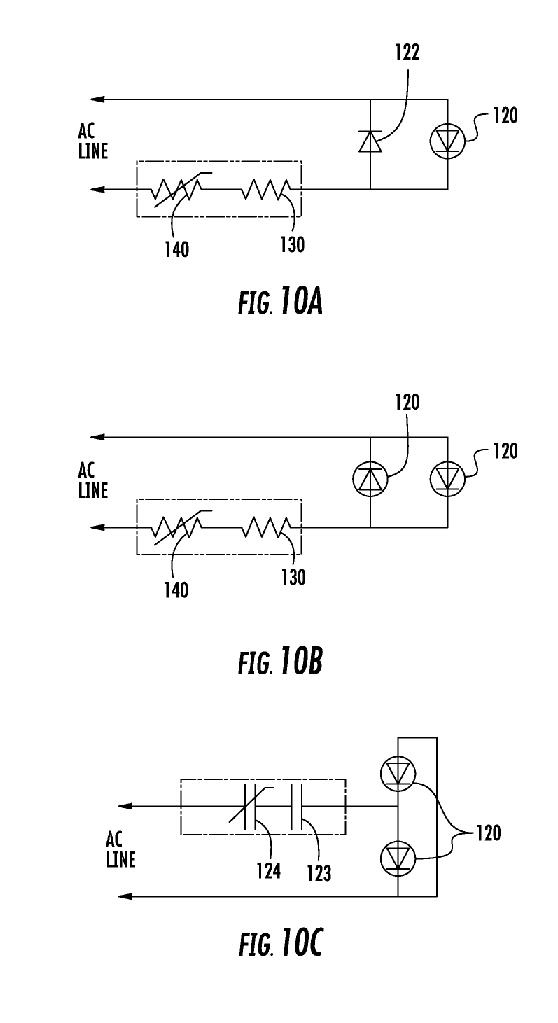

FIGS. 10A, 10B and 10C illustrate three exemplary circuits adapting the present invention to AC LED systems. In these systems the LEDs are used to rectify an AC source. LED 120 illuminates during the half cycle in which it is in forward bias. In FIG. 10A, there is an AC line signal across a parallel combination of LED 120 and diode 122. Shown in a series configuration, resistor 130 and thermistor 140 are placed in series with the incoming AC signal. Referring now to FIG. 10B, there is illustrated an AC line across a parallel configuration of LEDs 120 oriented in an opposite polarity. Those knowledgeable in the art would recognize that obtaining the objectives of current limiting and temperature drift compensation in AC LED circuits can be achieved using RC combinations, where low and high TCC (temperature coefficient of capacitance) capacitors can be combined to achieve the desirable impedance and temperature response. The above noted RC combinations include those where only capacitors are used, an example of which is shown in FIG. 10C. The circuit of FIG. 10C includes a capacitor 123 and a high TCC capacitor 124 in series with the incoming AC signal. The capacitors may be trimmed similarly to the TCR trimming described hereinabove.

The combination of the low and high TCC capacitors can be designed to limit the current by providing the required impedance governed by the following equation

C=1/iwZ Equation (3)

where C is the capacitance, w is 2π times the system frequency, and Z is the required current limiting impedance. A target TCC can be calculated to compensate for the LED temperature drift in the same fashion described for the resistor configuration above.

Capacitors for this application may have values greater than 100 uF and TCC values smaller (more negative) than −1000 ppm/c. Non-polarized capacitor technologies that obtain both high value and negative TCR include multi-layered ceramic capacitors with dielectrics of the Barium Titinate family. In some circuit topologies, polarized capacitors may be used including those with electrolytic or Tantalum based dielectrics. Similarly, to that described with the resistor topology, the combination of a low TCC and a high TCC capacitor may provide the required total impedance needed to limit current while setting the total TCC to the target value. A combination of resistors and capacitors (RC network) may be designed to reduce the nominal values of the capacitors and resistors, obtain tighter tolerances of the total temperature coefficient, and obtain a more linear temperature response as compared to that which can be achieved with capacitors alone.

Those knowledgeable in the art would recognize that the circuit of FIGS. 10A, 10B and 10C are trivial configurations of a class of circuits commonly referred to as AC LED systems. More complex configurations including large arrays of LEDs and intricate LED array configurations can be used. Any of these configurations could benefit by integrating the present invention to simultaneously limit the current and compensate for temperature drifts, while maintaining functionality with most common light dimming mechanisms.

Although the invention has been described and pictured in an exemplary form with a certain degree of particularity, it is understood that the present disclosure of the exemplary form has been made by way of example, and that numerous changes in the details of construction and combination and arrangement of parts and steps may be made without departing from the spirit and scope of the invention as set forth in the claims hereinafter.

What is claimed is:

1. A system for providing constant current to a plurality of LEDs (Light Emitting Diodes), the system comprising:
a low TCR (Temperature Coefficient of Resistance) resistor coupled to one of the plurality of LEDs; and
a high TCR resistor coupled to the one of the plurality of LEDs and the low TCR resistor, the combination of the low and high TCR resistors resulting in an effective resistance and effective TCR simultaneously limiting the constant current and compensating for a forward voltage shift of the one of the plurality of LEDs as a function of temperature.

2. The system of claim 1 further comprising a fuse coupled to the high TCR resistor, the fuse allowing the system to operate if a single LED within the plurality of LEDs fails to short-circuit.

3. The system of claim 1 wherein the effective TCR is approximately 1000 ppm/° C.

4. The system of claim 1 wherein the high TCR resistor is located proximate to the one of the plurality of LEDs to facilitate temperature tracking between the one of the plurality of LEDs and the high TCR resistor.

5. The system of claim 4 wherein the high TCR resistor is housed in a package with the one of the plurality of LEDs.

6. The system of claim 1 wherein the plurality of LEDs are driven using alternating current (AC).

7. The system of claim 1 wherein the low TCR resistor and the high TCR resistor are integrated into a package of at least one LED die.

8. A circuit for providing constant current to at least one LED (Light Emitting Diode), the circuit comprising:
a substrate;
a high TCR resistive film on the substrate; and
a low TCR resistive film on the substrate,
the high TCR and low TCR resistive films limit the constant current in the circuit at a given temperature and compensate for a forward voltage shift of the at least one LED as a function of temperature.

9. The circuit of claim 8 further comprising at least one LED.

10. The circuit of claim 8 wherein the high TCR resistive film comprises a layer of nickel over tantalum formed on the substrate.

11. The circuit of claim 8 wherein the low TCR resistive film comprises a selectively etched layer of tantalum etched from the layer of nickel over tantalum.

12. The circuit of claim 8 wherein the substrate is ceramic.

13. The circuit of claim 8 further comprising a thin film fuse coupled to the high and low TCR resistive films.

14. The circuit of claim 8 wherein the substrate, the high TCR resistive film and the low TCR resistive film are housed in the same package as at least one LED die.

15. The circuit of claim 8 wherein the high TCR resistive film is located proximate to the at least one LED to facilitate temperature tracking between the at least one LED and the high TCR resistive film.

16. The circuit of claim 8 wherein the effective TCR is approximately 1000 ppm/° C.

17. A metal strip circuit for providing constant current to at least one LED (Light Emitting Diode), the circuit comprising:
a first piece of material with high resistivity and low TCR;
a second piece of material with high resistivity and high TCR attached to the first piece forming an effective resistance and effective TCR that compensates for a forward voltage shift of the at least one LED as a function of temperature and limits the constant current in the circuit at a given temperature;
an upper piece of material and a lower piece of material, each with high conductivity, disposed on each end of the attached first and second piece of material, the upper piece being distal to the second piece of material and the lower piece being distal to the first piece of material

18. The circuit of claim 17 wherein each of the first, second, upper and lower pieces are substantially coplanar.

19. The circuit of claim 17 wherein the effective resistance and TCR is trimmed by implementing a first plurality of cuts in the first piece of material and a second plurality of cuts in the second piece of material.

20. The circuit of claim 19 wherein the effective TCR is approximately 1000 ppm/° C.

21. The circuit of claim 17 wherein the second piece of material is located proximate to the at least one LED to facilitate temperature tracking between the at least one LED and the second piece of material.

22. The circuit of claim 17 further comprising at least one LED.

23. A method of providing an LED with constant current, the method comprising:
identifying portions of a plurality of LEDs to power;
identifying a resistor value to limit the constant current through the identified portion of the plurality of LEDs at a certain temperature;
identifying a TCR value to compensate for a forward voltage shift of the LEDs;
thermally coupling a plurality of resistive elements that provide the identified resistor value and the identified TCR value to at least one of the identified portions of a plurality of LEDs; and
powering the LED with a constant voltage source.

24. The method of claim 23 further comprising identifying a fuse to allow the plurality of LEDs to operate if an LED fails to short-circuit.

25. The method of claim 23 further comprising trimming the resistive elements to compensate for manufacturing tolerances of Vf in the LEDs.

26. A system for providing constant current, the system comprising:
a first resistor coupled a device to be powered; and
a second resistor coupled to the device to be powered and the first resistor,
wherein the first and second resistors limit the constant current provided to the device at a given temperature and compensate for a forward voltage shift of the device as a function of temperature.

27. The system of claim 26 further comprising a fuse coupled to the first and second resistors.

28. An LED system comprising:
a circuit for providing constant current to at least one LED including:
a substrate;
a high TCR resistive film on the substrate; and
a low TCR resistive film on the substrate;
wherein the high and low TCR resistive films limit the constant current in the circuit at a given temperature and compensate for a forward voltage shift of the at least one LED as a function of temperature,
at least one LED electrically coupled to the circuit; and
a termination chip housing the at least one LED and the circuit and providing increased thermal conductivity between the circuit and the at least one LED.

29. The system of claim 28 wherein the high TCR resistive film comprises a layer of nickel over tantalum formed on the substrate.

30. The system of claim 29 wherein the low TCR resistive film comprises a selectively etched layer of tantalum etched from the layer of nickel over tantalum.

31. The system of claim 28 wherein the substrate is ceramic.

32. The system of claim 28 further comprising a thin film fuse coupled to the high and low TCR resistive films.

33. The system of claim 28 wherein the effective TCR is approximately 1000 ppm/° C.

34. A system for providing constant current to a plurality of LEDs (Light Emitting Diodes), the system comprising:
a low TCC (Temperature Coefficient of Capacitance) capacitor coupled to one of the plurality of LEDs; and
a high TCC capacitor coupled to the one of the plurality of LEDs and the low TCC capacitor, the combination of the low and high TCC capacitors resulting in an effective capacitance and effective TCC simultaneously limiting the constant current and compensating for a forward voltage shift of the one of the plurality of LEDs as a function of temperature.
